(19) United States
(12) Patent Application Publication
(10) Pub. No.: US 2025/0079805 A1
(43) Pub. Date: Mar. 6, 2025

(54) TERAHERTZ WAVE DETECTION DEVICE AND TERAHERTZ WAVE DETECTION METHOD

(71) Applicant: HAMAMATSU PHOTONICS K.K., Hamamatsu-shi (JP)

(72) Inventors: Hisanari TAKAHASHI, Hamamatsu-shi (JP); Kazuue FUJITA, Hamamatsu-shi (JP); Tatsuo DOUGAKIUCHI, Hamamatsu-shi (JP)

(73) Assignee: HAMAMATSU PHOTONICS K.K., Hamamatsu-shi (JP)

(21) Appl. No.: 18/822,534

(22) Filed: Sep. 3, 2024

(30) Foreign Application Priority Data
Sep. 6, 2023 (JP) 2023-144279

(51) Int. Cl. H01S 5/34; G01N 21/3581

(52) U.S. Cl. CPC H01S 5/3402; G01N 21/3581; H01S 2302/02

(57) ABSTRACT

A terahertz wave detection device includes a QCL element, an optical component disposed such that a laser beam emitted from the QCL element passes, and a photodetector that detects the laser beam having passed through the optical component. The QCL element has a semiconductor layer including an active layer in which unit stacked bodies including a light emitting layer and an injection layer are stacked in multiple stages. The unit stacked body is configured to be able to oscillate a first laser beam having a first wavelength and a second laser beam having a second wavelength. The QCL element is configured to change oscillation degrees of the first and second laser beams in accordance with the incidence of the terahertz wave on the QCL element. The optical component is configured to cause either one of the first laser beam and the second laser beam to be incident on the photodetector.

### TECHNICAL FIELD

The present disclosure relates to a terahertz wave detection device and a terahertz wave detection method.

### CROSS-REFERENCE TO RELATED APPLICATIONS

This application claims the benefit of priority from Japanese Patent Application No. 2023-144279 filed on Sep. 6, 2023, the entire contents of which are incorporated herein by reference.

### BACKGROUND

In related art, a Golay cell (for example, see Patent Document 1 (Japanese Unexamined Patent Publication No. 2006-278366)), a pyroelectric photodetector, a Schottky barrier diode (for example, see Patent Document 2 (Japanese Unexamined Patent Publication No. 2013-178212)), a Fermi level control barrier diode, and the like are known as a photodetector of a terahertz wave.

### SUMMARY

However, the Golay cell and the pyroelectric photodetector have a problem that a response speed is slow although sensitivity is high. On the other hand, although the Schottky barrier diode and the Fermi level control barrier diode can detect the terahertz wave at a relatively high speed, there is a problem that the sensitivity is lowered in a terahertz band of 1 THz or more.

Therefore, an object of one aspect of the present disclosure is to provide a terahertz wave detection device and a terahertz wave detection method capable of detecting a terahertz wave with high sensitivity and at a high speed.

The present disclosure includes a terahertz wave detection device of the following [1] to [6] and a terahertz wave detection method of the following [7] to [10].

[1] A terahertz wave detection device includes a quantum cascade laser element having a light incident surface on which a terahertz wave to be detected is incident and a light emission surface from which a laser beam different from the terahertz wave is emitted, an optical component disposed such that the laser beam emitted from the light emission surface passes, and a photodetector configured to detect the laser beam having passed through the optical component. The quantum cascade laser element has a substrate, and a semiconductor layer provided on the substrate, and including an active layer formed with a cascade structure in which a light emitting layer and an injection layer are alternately stacked by stacking unit stacked bodies including the light emitting layer and the injection layer in multiple stages. In a subband level structure, the unit stacked body has a first light emission upper level, a second light emission upper level that is an energy level higher than the first light emission upper level, and a light emission lower level, and is configured to be able to oscillate a first laser beam that is mid-infrared light having a first wavelength generated by transition from the first light emission upper level to the light emission lower level and a second laser beam that is mid-infrared light having a second wavelength generated by transition from the second light emission upper level to the light emission lower level, the quantum cascade laser element is configured to change oscillation degrees of the first laser beam and the second laser beam in accordance with the incidence of the terahertz wave on the light incident surface, and the optical component is configured to cause either one of the first laser beam and the second laser beam to be incident on the photodetector.

According to the terahertz wave detection device, in a case where the terahertz wave to be detected is incident on the light incident surface of the quantum cascade laser element (hereinafter, referred to as a “QCL element”.), the oscillation degrees of the first laser beam and the second laser beam can be changed. As a result, a difference can be generated in a detection amount of the first laser beam or the second laser beam in the photodetector between a first state where the terahertz wave is incident on the light incident surface and a second state where the terahertz wave is not incident on the light incident surface. Such a difference in the detection amount is detected, and thus, it is possible to substantially detect the terahertz wave to be detected. In addition, since it is possible to cause the first laser beam or the second laser beam which is mid-infrared light to be incident on the photodetector instead of causing the terahertz wave to be detected to be directly incident on the photodetector, it is possible to detect the terahertz wave with high sensitivity and at a high speed by using the photodetector capable of detecting the mid-infrared light.

[2] The terahertz wave detection device of [1] further includes a switch disposed on an upstream side of the light incident surface on an optical path of the terahertz wave and configured to periodically switch between an ON state where the terahertz wave passes and an OFF state where the terahertz wave does not pass, and a measuring device configured to acquire a first detection signal detected by the photodetector in the ON state and a second detection signal detected by the photodetector in the OFF state based on a signal indicating a repetition frequency of the switch.

According to the configuration of the above [2], even in a case where the signal value detected by the photodetector is weak, the terahertz wave can be detected with high accuracy by analyzing the difference between the first detection signal and the second detection signal.

[3] In the terahertz wave detection device of [1] or [2], the photodetector is any one of an MCT detector, an InAs detector, an InAsSb detector, and a quantum well infrared detector.

According to the configuration of the above [3], the mid-infrared light emitted from the quantum cascade laser element can be detected with high sensitivity and at a high speed by using the photodetector operating with high sensitivity and at a high speed as the photodetector in the mid-infrared region, and the terahertz wave can be detected with high sensitivity and at a high speed.

[4] In the terahertz wave detection device of any one of [1] to [3], in a case where a predetermined drive current corresponding to the terahertz wave is injected, the quantum cascade laser element is configured such the first laser beam oscillates but the second laser beam does not oscillate in a first state where the terahertz wave is not incident on the light incident surface and the second laser beam oscillates in a second state where the terahertz wave is incident on the light incident surface.

According to the configuration of the above [4], the second laser beam can be generated only in a case where the terahertz wave is incident on the light incident surface, and the first laser beam can be reduced by the amount of the second laser beam. As a result, since a more remarkable difference can be generated in the detection amount of the first laser beam or the second laser beam in the photodetector between the first state and the second state, the terahertz wave can be detected with high accuracy.

[5] In the terahertz wave detection device of any one of [1] to [4], the substrate has a first end surface that is an end surface of the substrate on one side in a first direction that is a resonance direction of the quantum cascade laser element and constitutes the light incident surface, and a second end surface that is positioned on a side opposite to the first end surface in the first direction, and the first end surface is inclined with the first direction to be away from the active layer toward the second end surface side along the first direction.

According to the configuration of the above [5], the terahertz wave to be detected is caused to be incident on the first end surface in the direction (direction inclined to approach the active layer from the first end surface side toward the second end surface side along the first direction) inclined with respect to the first direction, and thus, the optical loss of the terahertz wave due to reflection at the first end surface can be suppressed. Accordingly, the terahertz wave can be suitably guided to the active layer.

[6] In the terahertz wave detection device of [5], an inclination angle of the first end surface with respect to a surface orthogonal to the first direction substantially coincides with a Cherenkov radiation angle corresponding to the active layer.

According to the configuration of the above [6], the terahertz wave to be detected is caused to be incident substantially perpendicular to the first end surface, it is possible to more efficiently change the oscillation degree of the first laser beam or the second laser beam while suppressing the optical loss of the terahertz wave due to reflection on the first end surface. As a result, the terahertz wave can be detected with higher accuracy.

[7] A terahertz wave detection method for detecting a terahertz wave to be detected by using the terahertz wave detection device of any one of [1] to [6] includes continuously acquiring a signal value indicating a detection result of the photodetector in a predetermined target period and detecting the terahertz wave in accordance with detection of a change in the signal value.

According to the terahertz wave detection method of the above [7], the terahertz wave can be detected with high sensitivity and at a high speed by detecting the change in the output value (signal value) of the photodetector generated in a case where the terahertz wave is incident on the light incident surface using the terahertz wave detection device.

[8] The terahertz wave detection method of [7] further includes setting a polarization surface of the terahertz wave incident on the light incident surface and a polarization surface of the laser beam emitted from the light emission surface to be parallel to each other.

According to the configuration of the above [8], the influence of the terahertz wave on the active layer can be increased by causing the polarization surface of the terahertz wave to coincide with the polarization surface (that is, a surface parallel to the resonance direction of the QCL element and the stacking direction of the active layers) of the laser beam emitted from the light emission surface. As a result, the changes in the oscillation degrees of the first laser beam and the second laser beam corresponding to the incidence of the terahertz wave on the light incident surface can be increased, and the terahertz wave can be detected with higher accuracy.

[9] The terahertz wave detection method of [6] or [7] further includes controlling an operation of the quantum cascade laser element such that a difference between a frequency of the first laser beam and a frequency of the second laser beam substantially coincides with a frequency of the terahertz wave.

According to the configuration of the above [9], it is possible to suitably increase the changes in the oscillation degrees of the first laser beam and the second laser beam corresponding to the incidence of the terahertz wave on the light incident surface. As a result, the terahertz wave can be detected with higher accuracy.

The terahertz wave detection method of any one of [7] to [9] further includes controlling an operation of the quantum cascade laser element such that the first laser beam oscillates but the second laser beam does not oscillate in a first state where the terahertz wave is not incident on the light incident surface and the second laser beam oscillates in a second state where the terahertz wave is incident on the light incident surface.

According to the configuration of the above [10], the second laser beam can be generated only in a case where the terahertz wave is incident on the light incident surface, and the first laser beam can be reduced by the amount of the second laser beam. As a result, since a more remarkable difference can be generated in the detection amount of the first laser beam or the second laser beam in the photodetector between the first state and the second state, the terahertz wave can be detected with higher accuracy.

According to one aspect of the present disclosure, it is possible to provide the terahertz wave detection device and the terahertz wave detection method capable of detecting the terahertz wave with high sensitivity and at a high speed.

### BRIEF DESCRIPTION OF THE DRAWINGS

FIG. 1 is a schematic configuration diagram of an experimental system including a terahertz wave detection device according to an embodiment;

FIG. 2 is a schematic configuration diagram of a QCL element;

FIG. 3 is a diagram schematically illustrating a stacked structure of the QCL element;

FIG. 4 is a diagram illustrating an example of a subband level structure in an active layer of the QCL element;

FIG. 5 is a diagram illustrating an example of a configuration of a unit stacked body constituting the active layer;

FIG. 6 is a diagram illustrating an example of a structure of the unit stacked body for one cycle in the active layer; and

FIG. 7 is a diagram illustrating an example of a relationship between polarization of a terahertz wave and an MCT signal value.

### DETAILED DESCRIPTION

Hereinafter, an embodiment of the present disclosure will be described in detail with reference to the drawings. Note that, in the following description, identical or equivalent elements are denoted by identical reference signs, and redundant description thereof will be omitted.

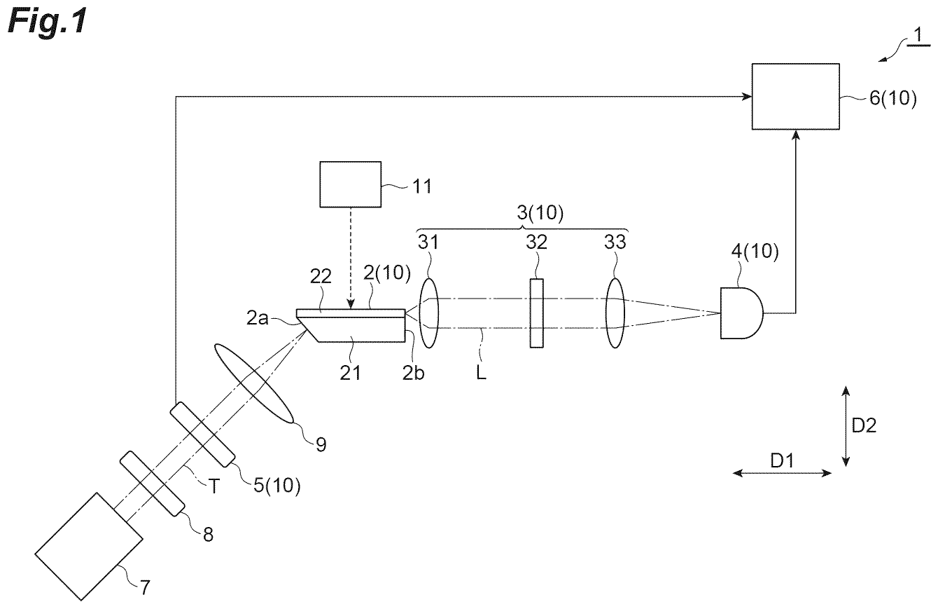

An optical system 1 as an experimental system including a terahertz wave detection device 10 of the present embodiment will be described with reference to FIG. 1. As illustrated in FIG. 1, the terahertz wave detection device 10 is used by being incorporated in the optical system 1, as a portion that detects a terahertz wave T to be detected. In the present embodiment, the terahertz wave detection device 10 includes a quantum cascade laser element (hereinafter, referred to as a “QCL element”.) 2, an optical component 3, a photodetector 4, an optical chopper 5 (switch), and a lock-in amplifier 6 (measuring device). The optical system 1 includes a light source 7, a polarizing element 8, a condenser lens 9, and a control unit 11 in addition to the terahertz wave detection device 10.

### [Configuration of QCL Element]

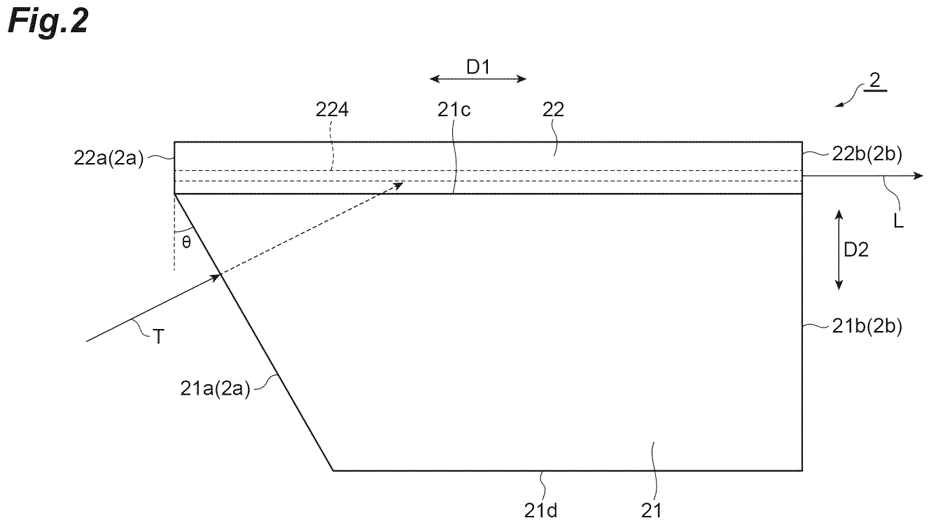

First, a configuration of the QCL element 2 will be described with reference to FIGS. 2 to 6. As illustrated in FIGS. 1 and 2, the QCL element 2 includes a light incident surface 2a on which the terahertz wave T to be detected is incident, and a light emission surface 2b that emits a laser beam L different from the terahertz wave T. The light incident surface 2a is a surface on one side (left side in FIG. 2) in a direction D1 (first direction) which is a resonance direction (direction in which end surfaces 22a and 22b of a semiconductor layer 22, to be described later, constituting a resonator face each other) of the QCL element 2. The light emission surface 2b is a surface on the other side (right side in FIG. 2) in the direction D1. The laser beam L is mid-infrared light (light having a wavelength of about 3 μm to 20 μm) generated by laser resonance between the end surfaces 22a and 22b of the semiconductor layer 22 of the QCL element 2 (specifically, a portion between end surfaces of a lower guide layer 223, an active layer 224, and an upper guide layer 225 to be described later).

The QCL element 2 is configured to be able to oscillate a first laser beam that is mid-infrared light having a wavelength λ₁ (first wavelength) and a second laser beam that is mid-infrared light having a wavelength λ₂ (second wavelength) different from the wavelength λ₁. In addition, the QCL element 2 is configured to change oscillation degrees of the first laser beam (λ₁) and the second laser beam (λ₂) in accordance with the incidence of the terahertz wave T on the light incident surface 2a. Although the wavelength λ₁ and the wavelength λ₂ depend on magnitude of a drive current of the QCL element 2, in the present embodiment, as an example, the wavelength λ₁ is 6.9 μm and the wavelength λ₂ is 6.6 μm under a predetermined current condition (in the present embodiment, in a case where a drive current of 490 mA is injected into the QCL element 2). In addition, the QCL element 2 is configured such that, in a case where a predetermined drive current I (in the present embodiment, the above-described 490 mA) corresponding to the terahertz wave T is injected, the first laser beam oscillates in a first state where the terahertz wave T is not incident on the light incident surface 2a but the second laser beam does not oscillate and the second laser beam oscillates in a second state where the terahertz wave T is incident on the light incident surface 2a. Hereinafter, an example of the configuration of the QCL element 2 having the above-described characteristics will be described.

The QCL element 2 includes a substrate 21 and a semiconductor layer 22. As an example, the substrate 21 is a semiconductor substrate such as an InP single crystal substrate. The substrate 21 is formed in a rectangular plate shape, and has an end surface 21a (first end surface), an end surface 21b (second end surface), a principal surface 21c, and a back surface 21d. The end surface 21a is a surface on one side (left side in FIG. 2) in the direction D1, and constitutes a part of the light incident surface 2a of the QCL element 2. The end surface 21b is a surface on the other side (right side in FIG. 2) in the direction D1, and constitutes a part of the light emission surface 2b of the QCL element 2. The principal surface 21c is a surface on which the semiconductor layer 22 is provided, and the back surface 21d is a surface opposite to the principal surface 21c.

The principal surface 21c and the back surface 21d are parallel to each other. The end surface 21b is a surface perpendicular to the direction D1, that is, a surface parallel to a direction D2 (second direction) perpendicular to the principal surface 21c. On the other hand, as illustrated in FIG. 2, the end surface 21a is inclined by an inclination angle θ with respect to a plane perpendicular to the direction D1 as viewed from a direction orthogonal to the direction D1 and the direction D2. The end surface 21a is inclined with respect to the direction D1 to be away from the active layer 224 (semiconductor layer 22) toward the end surface 21b side along the direction D1. In other words, the end surface 21a is inclined with respect to the direction D2 to approach the end surface 21b to be away from the active layer 224 along the direction D2 (that is, from the principal surface 21c side toward the back surface 21d side).

A length of the substrate 21 (length in the direction D1) is, for example, about several hundred μm to several mm. A width of the substrate 21 (length in direction orthogonal to directions D1 and D2) is, for example, about several hundred μm to several mm. A thickness of the substrate 21 (length in the direction D2) is, for example, about several hundred μm. As an example, the length of the substrate 21 is about 3 mm, the width of the substrate 21 is about 1 mm, and the thickness of the substrate 21 is about 300 μm.

The semiconductor layer 22 is provided on the principal surface 21c of the substrate 21. A thickness of the semiconductor layer 22 (length in the direction D2) is, for example, about 10 μm to 20 μm. The semiconductor layer 22 has the end surface 22a that is continuous with the end surface 21a of the substrate 21 and constitutes a part of the light incident surface 2a, and the end surface 22b that is continuous with the end surface 21b of the substrate 21 and constitutes a part of the light emission surface 2b. The end surfaces 22a and 22b are surfaces perpendicular to the direction D1. The end surfaces 22a and 22b are, for example, cleavage surfaces formed by cleavage.

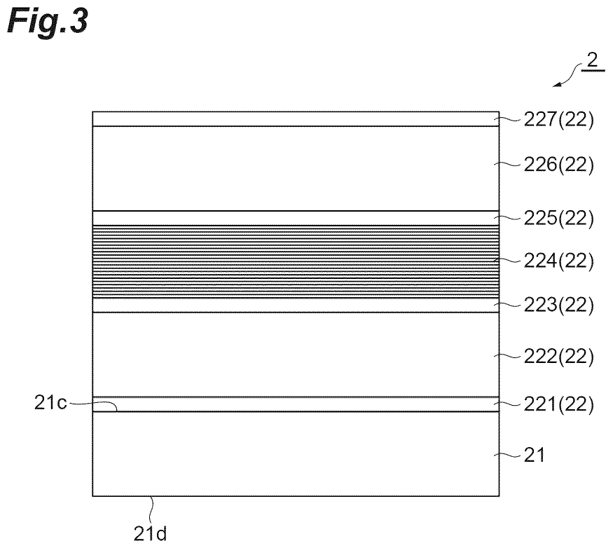

As illustrated in FIG. 3, the semiconductor layer 22 is formed by stacking a lower contact layer 221, a lower cladding layer 222, the lower guide layer 223, the active layer 224, the upper guide layer 225, an upper cladding layer 226, and an upper contact layer 227 in this order on the principal surface 21c of the substrate 21.

The lower contact layer 221 is, for example, a high-concentration Si-doped InGaAs layer (Si: 1.0×10¹⁸ cm⁻³) having a thickness of about 200 nm, and is provided on the principal surface 21c of the substrate 21.

The lower cladding layer 222 is, for example, a Si-doped InP layer (Si: 1.5×10¹⁶ cm⁻³) having a thickness of about 5 μm, and is provided on the lower contact layer 221.

The lower guide layer 223 is, for example, a Si-doped In_{0.53}Ga_{0.47}As layer (Si: 1.5×10¹⁶ cm⁻³) having a thickness of about 100 nm, and is provided on the lower cladding layer 222.

The active layer 224 is a layer in which a quantum cascade structure is formed, and is provided on the lower guide layer 223. Details of the active layer 224 will be described later.

The upper guide layer 225 is, for example, a Si-doped In_{0.53}Ga_{0.47}As layer (Si: 1.5×10¹⁶ cm⁻³) having a thickness of about 300 nm, and is provided on the active layer 224.

The upper cladding layer 226 is, for example, a Si-doped InP layer (Si: 1.5×10¹⁶ cm⁻³) having a thickness of about 5 μm, and is provided on the upper guide layer 225.

The upper contact layer 227 is, for example, a high-concentration Si-doped InP layer (Si: 1.5×10¹⁸ cm⁻³) having a thickness of about 15 nm, and is provided on the upper cladding layer 226.

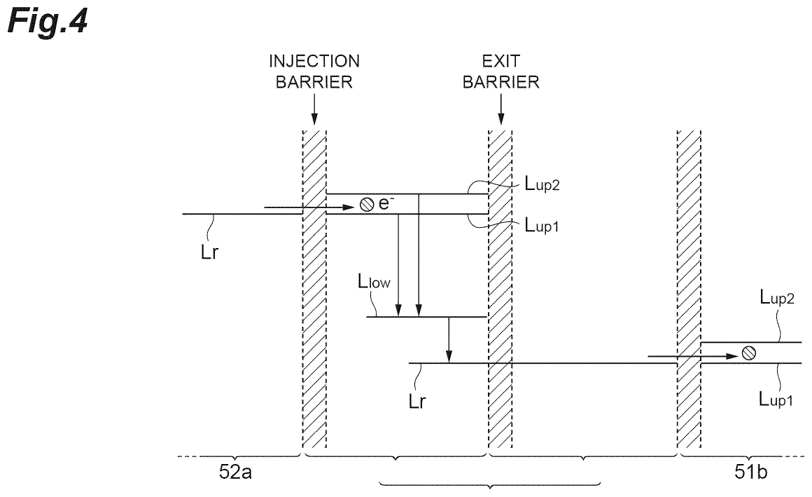

A structure of the active layer 224 of the present embodiment will be described with reference to FIGS. 4 to 6. The active layer 224 has a cascade structure in which a quantum well light emitting layer (light emitting layer 51) used for generating light and an electron injection layer (injection layer 52) used for injecting electrons (carriers) into the light emitting layer 51 are alternately stacked in multiple stages. Specifically, a semiconductor stacked structure including the light emitting layer 51 and the injection layer 52 is used as a unit stacked body 50 for one cycle, and the unit stacked bodies 50 are stacked in multiple stages to form the active layer 224 having the cascade structure.

As illustrated in FIG. 4, each of the plurality of unit stacked bodies 50 included in the active layer 224 is constituted by the light emitting layer 51 and the injection layer 52. As will be described later, the light emitting layer 51 and the injection layer 52 are formed to have a predetermined quantum well structure including quantum well layers (well layers W1 to W11) and quantum barrier layers (barrier layers B1 to B11). As a result, in the unit stacked body 50, a subband level structure which is an energy level structure by the quantum well structure is formed.

The active layer 224 has a dual-upper-state (DAU) structure as disclosed in, for example, Japanese Patent No. 5523759 and Japanese U.S. Pat. No. 6,276,758. That is, the unit stacked body 50 included in the active layer 224 has two light emission upper levels. As an example, in the subband level structure, the unit stacked body 50 has a first light emission upper level Lᵤₚ₁, a second light emission upper level Lᵤₚ₂ which is an energy level higher than the first light emission upper level, and a single light emission lower level L_{low}, as levels related to light emission by inter-subband transition. However, the level structure of the unit stacked body 50 is not limited to the above structure. For example, the unit stacked body 50 may have a plurality of light emission lower levels.

In addition, in the subband level structure illustrated in FIG. 4, a relaxation level Lᵣ is provided as an energy level lower than the light emission lower level L_{low}. The relaxation level Lᵣ is a level for extracting electrons after light emission transition from the light emission lower level L_{low}, and is preferably set such that an energy difference between the light emission lower level L_{low} and the relaxation level Lᵣ becomes an energy E_{LO} of an LO phonon. In addition, in the present embodiment, the relaxation level Lᵣ which is a base level within the injection layer 52 is designed to be strongly coupled with the first light emission upper level Lᵤₚ₁ in a light emitting layer 51b of a unit stacked body 50 at a subsequent stage under a condition of an operation electric field.

In addition, in the unit stacked body 50 illustrated in FIG. 4, an injection barrier layer for electrons e injected from an injection layer 52a of a unit stacked body 50 at a preceding stage into the light emitting layer 51 is provided between the light emitting layer 51 and the injection layer 52a. In addition, an exit barrier layer for electrons from the light emitting layer 51 to the injection layer 52 is provided between the light emitting layer 51 and the injection layer 52. These barrier layers are provided as necessary by a specific stacked structure and subband level structure of the active layer 224 including the light emitting layer 51 and the injection layer 52.

In the present embodiment, in such a subband level structure, electrons e⁻ from the relaxation level Lᵣ of the injection layer 52a at the preceding stage are injected into the light emitting layer 51 via the injection barrier layer, and thus, the first light emission upper level Lᵤₚ₁ coupled to the relaxation level Lᵣ is strongly excited.

The electrons injected into the first light emission upper level Lᵤₚ₁ make light emission transition to the light emission lower level L_{low}, and light having a wavelength A corresponding to an energy difference between subband levels of the first light emission upper level Lᵤₚ₁ and the light emission lower level L_{low} is generated and emitted. The electrons having transitioned to the light emission lower level L_{low} are relaxed to the relaxation level Lᵣ by a relaxation procedure such as LO phonon scattering. As described above, the electrons are extracted from the light emission lower level L_{low} by using the relaxation level Lᵣ, and thus, an inverted distribution for realizing laser oscillation is formed between the first light emission upper level Lᵤₚ₁ and the light emission lower level L_{low}. In addition, the electrons relaxed from the light emission lower level L_{low} to the relaxation level Lᵣ are injected in a cascade manner from the relaxation level Lᵣ into the first light emission upper level Lᵤₚ₁ in the light emitting layer 51b at the subsequent stage via the exit barrier layer and the injection layer 52.

Such electron injection, light emission transition, and relaxation are repeated in the plurality of unit stacked bodies 50, and thus, generation of light in a cascade manner occurs in the active layer 224. That is, a large number of light emitting layers 51 and injection layers 52 are alternately stacked. Thus, the electrons sequentially move through the plurality of unit stacked bodies 50 in a cascade manner, and light having a wavelength λ₁ is generated at the time of inter-subband transition in each unit stacked body 50. Such light is resonated in an optical resonator (that is, a resonator formed by the lower guide layer 223, the active layer 224, and the end surfaces 22a and 22b of the upper guide layer 225) of the QCL element 2, and thus, a laser beam (first laser beam) having a wavelength λ₁ is generated.

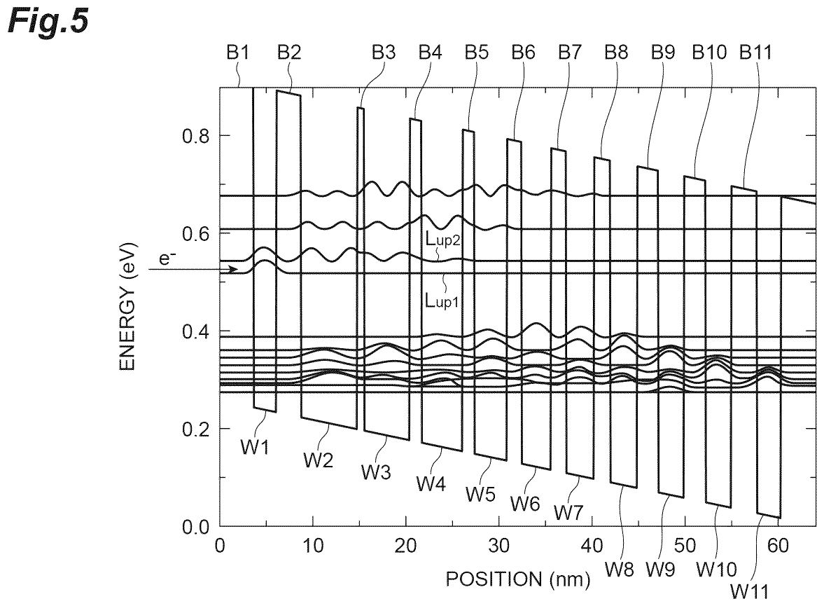

As illustrated in FIG. 5, in the present embodiment, the unit stacked body 50 for one cycle is formed as a quantum well structure in which 11 well layers W1 to W11 and 11 barrier layers B1 to B11 are alternately stacked.

The well layers W1 to W11 are constituted by In_{0.53}Ga_{0.47}As layers. In addition, the barrier layers B1 to B11 are constituted by In_{0.48}Al_{0.52}As layers. As a result, the active layer 224 includes an InGaAs/InAlAs quantum well structure lattice-matched to the substrate 21 which is an InP substrate.

In the unit stacked body 50, a stacked portion including the well layers W1 to W4 and the barrier layers B1 to B4 mainly functions as the light emitting layer 51. In addition, a stacked portion including the well layers W5 to W11 and the barrier layers B5 to B11 mainly functions as the injection layer 52.

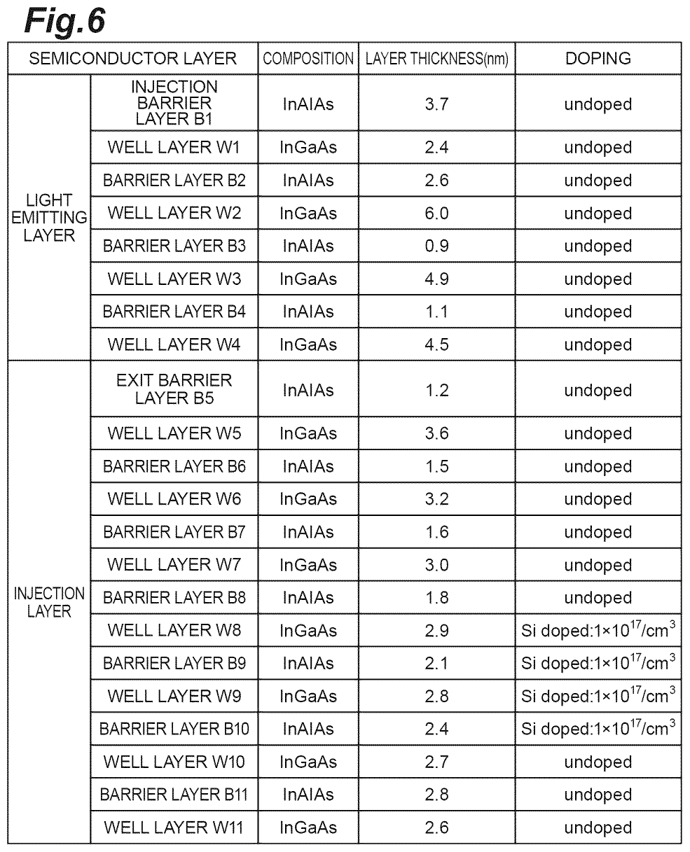

In addition, among semiconductor layers of the light emitting layer 51, the barrier layer B1 at a first stage is positioned between the injection layer 52a (see FIG. 4) at the preceding stage and the light emitting layer 51, and serves as the injection barrier layer for the electrons from the injection layer 52a at the preceding stage to the light emitting layer 51. Similarly, among semiconductor layers of the injection layer 52, the barrier layer B5 at a first stage is positioned between the light emitting layer 51 and the injection layer 52 and serves as the exit barrier layer for the electrons from the light emitting layer 51 to the injection layer 52. FIG. 6 illustrates an example of a specific structure of the unit stacked body 50 for one cycle in the active layer 224. In the present embodiment, with such a layer structure, a designed oscillation wavelength of the QCL element 2 is set to around 6.5 μm.

In the present embodiment, when a predetermined drive current I is injected into the QCL element 2 due to the structure of the active layer 224 (unit stacked body 50) described above, the current first flows into the first light emission upper level Lᵤₚ₁ on a low energy side among two light emission upper levels in the unit stacked body 50. Thus, at the start of an operation of the QCL element 2, the oscillation due to the light emission transition from the first light emission upper level Lᵤₚ₁ to the light emission lower level Low is easily started. In addition, as described above, the relaxation level Lᵣ within the injection layer 52 is configured to be strongly coupled with the first light emission upper level Lᵤₚ₁ in the light emitting layer 51b of the unit stacked body 50 at the subsequent stage. As a result, the drive current I of the QCL element 2 is adjusted, and thus, it is possible to cause only oscillation from the first light emission upper level Lᵤₚ₁ and not to cause oscillation from the second light emission upper level Lᵤₚ₂ in the above-described first state (that is, a state where the terahertz wave T is not incident on the light incident surface 2a). Further, in the present embodiment, a diffraction grating (in other words, a diffraction grating pattern configured to reduce an optical loss of the wavelength λ₁) for promoting oscillation of the wavelength λ₁ (in the present embodiment, 6.9 μm) is provided in the upper guide layer 225. More specifically, a diffraction grating having a cycle of 1080 nm is provided in the upper guide layer 225, and thus, the QCL element 2 is configured to mainly oscillate at the wavelength λ₁.

On the other hand, in the present embodiment, the drive current I is adjusted in accordance with a frequency of the terahertz wave T to be detected or the like, and thus, the oscillation from the second light emission upper level Lᵤₚ₂ can be caused in the above-described second state (that is, a state where the terahertz wave T is incident on the light incident surface 2a and is incident on the active layer 224). That is, when the terahertz wave T is incident on the active layer 224 (unit stacked body 50), a distribution of carriers in the first light emission upper level Lᵤₚ₁ and the second light emission upper level Lᵤₚ₂ changes, and as a result, the oscillation degrees of the first laser beam and the second laser beam change. More specifically, due to the influence of the terahertz wave T, some of the electrons concentrated in the first light emission upper level Lᵤₚ₁ move to the second light emission upper level Lᵤₚ₂, and thus, sufficient electrons are also supplied to the second light emission upper level Lᵤₚ₂, and a sufficient number of carriers are excited. In addition, as illustrated in FIG. 5, in the present embodiment, since overlap of wave functions of the second light emission upper level Lᵤₚ₂ and the light emission lower level L_{low} is designed to become sufficiently large and transition intensity from the second light emission upper level Lᵤₚ₂ to the light emission lower level L_{low} is also sufficiently large, the oscillation from the second light emission upper level Lᵤₚ₂ can be caused. As a result, the electrons injected into the second light emission upper level Lᵤₚ₂ make light emission transition to the light emission lower level L_{low}, and light having a wavelength λ₂ corresponding to an energy difference between subband levels of the second light emission upper level Lᵤₚ₂ and the light emission lower level L_{low} is generated and emitted. Accordingly, the oscillation degree of the second laser beam is increased. On the other hand, the movement of the carriers from the first light emission upper level Lᵤₚ₁ to the second light emission upper level Lᵤₚ₂ occurs as described above, and thus, the oscillation degree of the first laser beam decreases by this amount.

With the above-described configuration, under a predetermined current condition (state where the drive current I adjusted as described above is injected and operated), the QCL element 2 is configured to output the laser beam L including only the first laser beam having the wavelength A in the first state where the terahertz wave T is not incident on the QCL element 2, and output the laser beam L including not only the first laser beam having the wavelength λ₁ but also the second laser beam having the wavelength λ₂ in the second state where the terahertz wave T is incident on the QCL element 2.

Note that, as described above, the subband level structure in the unit stacked body 50 depends on the magnitude of the drive current I. That is, the wavelength λ₁ of the first laser beam generated based on the first light emission upper level Lᵤₚ₁ and the wavelength λ₂ of the second laser beam generated based on the second light emission upper level Lᵤₚ₂ can change depending on the magnitude of the drive current I. From the viewpoint of efficiently oscillating the second laser beam by the incidence of the terahertz wave T on the QCL element 2, it is preferable that the drive current I is adjusted such that a difference frequency Δf (=c(λ₁−λ₂)/(λ₁·λ₂)) between a frequency (c/λ₁) of the first laser beam and a frequency (c/λ₂) of the second laser beam substantially coincide with the frequency of the terahertz wave T. Such a terahertz wave T is caused to be incident on the active layer 224, and thus, the supply of the carriers to the second light emission upper level Lᵤₚ₂ as described above can be promoted, and the oscillation degree of the second laser beam can be effectively enhanced. Note that, in the above description, c represents a speed of light.

### [Description of Each Configuration of Optical System]

Next, an example of a configuration of the optical system 1 for detecting the terahertz wave T by using the QCL element 2 having the characteristics described above will be described.

The light source 7 is a light source that emits the terahertz wave T to be detected. A frequency range of the terahertz wave T emitted from the light source 7 is, for example, 0.1 THz or more and 10.0 THz or less. In the present embodiment, the light source 7 is a THz gas laser light source configured to emit a terahertz wave T having a frequency of 2.52 THz.

The polarizing element 8 is an optical element for changing a polarization direction (electric field vibration direction) of the terahertz wave T emitted from the light source 7. The polarizing element 8 includes, for example, a wire grid polarizer, a wave plate, or the like. In addition, the polarizing element 8 may be formed by a combination of a plurality of optical elements (for example, the above-described polarizer, wave plate, and the like). The polarizing element 8 may be used to set a polarization surface of the terahertz wave T and a polarization surface (that is, a surface parallel to both the direction D1 which is the resonance direction and the direction D2 which is the stacking direction of the active layer 224) of the laser beam L emitted from the light emission surface 2b of the QCL element 2 to be parallel to each other. Note that, in a case where the polarization surface of the terahertz wave T can be set to be parallel to the polarization surface of the QCL element 2 by adjusting a relative positional relationship (orientation) between the light source 7 and the QCL element 2, the polarizing element 8 may be omitted.

The optical chopper 5 is disposed on an upstream side of the light incident surface 2a of the QCL element 2 on an optical path of the terahertz wave T, and periodically switches between an ON state where the terahertz wave T passes and an OFF state where the terahertz wave T does not pass. A signal (reference signal) indicating a timing (repetition frequency) of switching between the ON state and the OFF state by the optical chopper 5 is sent to the lock-in amplifier 6.

The condenser lens 9 is a lens member that is disposed between the optical chopper 5 and the light incident surface 2a of the QCL element 2 and condenses the terahertz wave T having passed through the optical chopper 5 on the light incident surface 2a (in the present embodiment, the end surface 21a of the substrate 21). The condenser lens 9 is, for example, a lens for a terahertz wave band such as Tsurupica (registered trademark) having a focal length of 40 mm.

As illustrated in FIG. 2, in the present embodiment, the QCL element 2 is disposed such that the terahertz wave T collected by the condenser lens 9 is incident substantially perpendicularly to the end surface 21a of the substrate 21. The terahertz wave T incident on the end surface 21a in this manner reaches the active layer 224 of the semiconductor layer 22 through an inside of the substrate 21. As a result, as described above, in the active layer 224, the distribution of carriers in the first light emission upper level Lᵤₚ₁ and the second light emission upper level Lᵤₚ₂ changes, and the oscillation degrees of the first laser beam (λ₁) and the second laser beam (λ₂) change. Specifically, while the carriers (electrons) supplied to the second light emission upper level Lᵤₚ₂ increase, the carriers (electrons) supplied to the first light emission upper level Lᵤₚ₁ decrease. As a result, while the first laser beam included in the laser beam L decreases, the second laser beam is included in the laser beam L. Note that, the laser beam L is emitted radially from the end surface 22b of the semiconductor layer 22 (mainly the end surface of the active layer 224) along the direction D1.

The control unit 11 injects the drive current I into the QCL element 2, and controls the start or end of the injection, the injection amount, and the like. The control unit 11 is, for example, a computer device including a processor, a memory, and the like.

The optical component 3 is disposed such that the laser beam L emitted from the light emission surface 2b of the QCL element 2 passes therethrough. As an example, the optical component 3 includes a collimator lens 31, an optical filter 32, and a condenser lens 33. The optical component 3 includes the optical filter 32, and thus, any one (in the present embodiment, only the second laser beam) of the first laser beam (λ₁) and the second laser beam (λ₂) is caused to be incident on the photodetector 4.

The collimator lens 31 is a lens that collimates the laser beam L radially emitted from the light emission surface 2b. The collimator lens 31 is, for example, a ZnSe lens having a focal length of 1 mm.

The optical filter 32 is configured to guide only one of the first laser beam (λ₁) and the second laser beam (λ₂) to the condenser lens 33 at the subsequent stage. For example, a band-pass filter that transmits only a specific wavelength band, a diffraction grating that reflects only a specific wavelength, or the like can be used as the optical filter 32. In the present embodiment, the optical filter 32 is a band-pass filter configured to transmit the wavelength λ₂ but not transmit (absorb or reflect) the wavelength λ₁.

The condenser lens 33 is a lens that condenses the laser beam L (in the present embodiment, the second laser beam) having passed through the optical filter 32 toward a light receiving surface of the photodetector 4. The condenser lens 33 is, for example, a ZnSe lens having a focal length of 50 mm.

The photodetector 4 detects the laser beam L having passed through the optical component 3. In the present embodiment, the photodetector 4 is an MCT photodetector that detects the second laser beam having passed through the optical filter 32 and incident on the light receiving surface of the photodetector 4. Here, in the first state where the terahertz wave T is not incident on the QCL element 2, the second laser beam is not generated, and only the first laser beam is output as the laser beam L from the QCL element 2. Thus, in the first state, since all of the laser beams L including only the first laser beam having the wavelength λ₁ is cut by the optical filter 32, a signal value of the photodetector 4 becomes a value close to 0. On the other hand, in the second state, since the second laser beam having the wavelength λ₂ passes through the optical filter 32, the second laser beam (laser beam L) is detected by the photodetector 4, and a significant signal value is obtained.

It is preferable that the photodetector 4 has good sensitivity to mid-infrared light and has a response speed higher than a response speed of a photodetector that can be used in a terahertz wave band, such as a pyroelectric photodetector and a Golay cell. The laser beam L (in the present embodiment, the second laser beam having the wavelength λ₂ derived from the terahertz wave T) is detected by using such a photodetector 4, and thus, the terahertz wave T can be detected at a high speed without deteriorating detection sensitivity as compared with a case where the terahertz wave T is directly detected by the pyroelectric photodetector, the Golay cell, and the like. From the above viewpoint, for example, it is preferable that any one of an MCT photodetector, an InAs photodetector, an InAsSb photodetector, and a quantum well infrared photodetector (QWIP) is used as the photodetector 4. Specific examples of the QWIP include a quantum cascade photodetector (QCD).

The lock-in amplifier 6 acquires a first detection signal detected by the photodetector 4 in the ON state and a second detection signal detected by the photodetector 4 in the OFF state based on the signal (reference signal) indicating the repetition frequency of the optical chopper 5.

### [Effects of Terahertz Wave Detection Device]

According to the terahertz wave detection device 10 described above, in a case where the terahertz wave T to be detected is set to be incident on the light incident surface 2a of the QCL element 2 (in other words, in a case where the terahertz wave T to be detected is generated), the oscillation degrees of the first laser beam and the second laser beam in the QCL element 2 can be changed. As a result, a difference can be generated in a detection amount of the first laser beam or the second laser beam (in the present embodiment, the second laser beam) in the photodetector 4 between the first state where the terahertz wave T is incident on the light incident surface 2a (in the present embodiment, the end surface 21a of the substrate 21) and the second state where the terahertz wave T is not incident on the light incident surface 2a. In the present embodiment, in the first state, a signal value indicating the detection amount of the second laser beam in the photodetector 4 becomes 0, and in the second state, a signal value indicating the detection amount of the second laser beam in the photodetector 4 becomes a value larger than 0 corresponding to the light intensity. Such a difference in detection amount is detected, and thus, the terahertz wave T to be detected can be substantially detected. In addition, since it is possible to cause the first laser beam or the second laser beam (in the present embodiment, the second laser beam) which is mid-infrared light to be incident on the photodetector 4 instead of causing the terahertz wave T to be detected to directly be incident on the photodetector 4, it is possible to detect the terahertz wave T with high sensitivity and at a high speed by using the photodetector 4 capable of detecting mid-infrared light.

In addition, the terahertz wave detection device 10 includes the optical chopper 5 and the lock-in amplifier 6 described above. As a result, even in a case where the signal value detected by the photodetector 4 (the signal value corresponding to the second laser beam detected in the second state) is weak, the terahertz wave T can be detected with high accuracy by analyzing a difference between the first detection signal and the second detection signal. For example, in a case where the terahertz wave T is emitted from the light source 7, the terahertz wave T does not reach the QCL element 2 in an OFF state where the terahertz wave T is shielded by the optical chopper 5. Thus, in a period in which the terahertz wave T is emitted from the light source 7, the first detection signal detected in the ON state where the terahertz wave T reaches the QCL element 2 indicates a signal value corresponding to the detection result of the second laser beam generated in accordance with the terahertz wave T. On the other hand, the second detection signal indicates a signal value in a state where the second laser beam is not detected. Here, it is considered that the second detection signal ideally becomes 0, but it is also considered that the second detection signal indicates a value larger than 0 due to the influence of noise. In addition, in a case where the second laser beam generated by the incidence of the terahertz wave T is weak, the signal value of the first detection signal is very small, and in a case where the first detection signal is viewed alone, it may not be possible to determine whether the value is due to the second laser beam or due to noise. In such a case, the difference between the first detection signal and the second detection signal is analyzed, and thus, it is possible to detect that the second laser beam is detected in the ON state (that is, the terahertz wave T is incident on the QCL element 2) with high accuracy.

The photodetector 4 may be any of an MCT photodetector, an InAs photodetector, an InAsSb photodetector, and a QWIP. In this case, the photodetector 4 that operates with high sensitivity and at a high speed is used as a photodetector in a mid-infrared region, and thus, it is possible to detect the mid-infrared light (in the present embodiment, the laser beam L including the second laser beam having the wavelength 22) emitted from the QCL element 2 with high sensitivity and at a high speed. It is possible to eventually detect the terahertz wave T with high sensitivity and at a high speed.

In addition, the QCL element 2 is configured such that, in a case where a predetermined drive current I corresponding to the terahertz wave T is injected, the first laser beam oscillates in the first state where the terahertz wave T is not incident on the light incident surface 2a and the second laser beam does not oscillate and the second laser beam oscillates in the second state where the terahertz wave Tis incident on the light incident surface 2a. According to the above configuration, the second laser beam can be generated only in a case where the terahertz wave T is incident on the light incident surface 2a, and the first laser beam can be reduced by this amount. As a result, it is possible to generate a more remarkable difference in the detection amount of the first laser beam or the second laser beam (in the present embodiment, the second laser beam) in the photodetector 4 between the first state and the second state. As a result, the terahertz wave T can be detected with high accuracy.

In addition, as illustrated in FIG. 2, the end surface 21a of the substrate 21 constituting the light incident surface 2a is inclined with respect to the direction D1 to be away from the active layer 224 toward the end surface 21b side (that is, the right side in FIG. 2) along the direction D1. According to the above configuration, the terahertz wave T to be detected is caused to be incident on the end surface 21a in the direction (as illustrated in FIG. 2, a direction inclined to approach the active layer 224 from the end surface 21a side toward the end surface 21b side along the direction D1) inclined with respect to the direction D1, and thus, an incident angle of the terahertz wave T with respect to the end surface 21a is reduced. Accordingly, an optical loss of the terahertz wave T due to reflection on the end surface 21a can be suppressed, and the terahertz wave T can be suitably guided to the active layer 224. More specifically, since a thickness (length in the direction D2) of the active layer 224 is very small, it is not easy to set a sufficient amount of the terahertz wave T to be incident from the end surface 22a of the active layer 224. On the other hand, as illustrated in FIG. 2, the terahertz wave T is incident through the substrate 21 in the direction inclined with respect to the direction D1, and thus, the terahertz wave T can be efficiently set to be incident on the active layer 224.

In addition, it is preferable that the inclination angle θ of the end surface 21a with respect to a surface orthogonal to the direction D1 is set to substantially coincide with a Cherenkov radiation angle corresponding to the active layer 224. Here, the “Cherenkov radiation angle corresponding to the active layer 224” is an angle formed by a radiation direction of the terahertz wave with the direction D1 in a case where both the first laser beam (λ₁) and the second laser beam (λ₂) described above oscillate within the active layer 224 and in a case where the terahertz wave corresponding to the difference frequency Δf (=c(λ₁−λ₂)/(λ₁·λ₂)) between the frequency (c/λ₁) of the first laser beam and the frequency (c/λ₂) of the second laser beam is generated in the active layer 224. In a case where a group refractive index of the substrate 21 with respect to the mid-infrared light is expressed as n_{MIR} and a refractive index of the substrate 21 with respect to the terahertz wave is expressed as n_{THz}, a Cherenkov radiation angle θ_{C} is expressed by the following Expression (1). Note that, although the Cherenkov radiation angle θ_{C} depends on the material of the substrate 21 (that is, the refractive index corresponding to the material) and the frequency of the terahertz wave, the Cherenkov radiation angle θ_{C} is, for example, about 5 degrees to 30 degrees.

θ_{C}=cos⁻¹(n_{MIR}/n_{THz}) (1)

According to the above configuration, the terahertz wave T to be detected is caused to be incident substantially perpendicular to the end surface 21a, and thus, it is possible to effectively increase the influence of the terahertz wave T on the active layer 224 while suppressing the optical loss of the terahertz wave T due to the reflection on the end surface 21a. It is possible to more efficiently change the oscillation degree of the first laser beam or the second laser beam. As a result, the terahertz wave T can be detected with higher accuracy. More specifically, in a case where the incident angle θ_{THz} of the terahertz wave T with respect to the active layer 224 and the Cherenkov radiation angle θ_{C} do not coincide with each other, there is a possibility that the mid-infrared light (MIR light) generated by the incidence of the terahertz wave T on the active layer 224 is output in a direction different from the resonance direction (direction D1) of the QCL element 2 and is not efficiently detected by the photodetector 4. On the other hand, as described above, the inclination angle θ coincides with the Cherenkov radiation angle θ_{C} and the terahertz wave T is caused to be incident substantially perpendicularly on the end surface 21a. Thus, the incident angle θ_{THz}, of the terahertz wave T and the Cherenkov radiation angle θ_{C} can coincide with each other. As a result, since an emission direction of the mid-infrared light generated by the incidence of the terahertz wave T on the active layer 224 can coincide with the resonance direction (direction D1), the mid-infrared light (that is, the mid-infrared light emitted from the light emission surface 2b along the direction D1) detected by the photodetector 4 can be efficiently generated.

### [Terahertz Wave Detection Method]

Next, an example of a terahertz wave detection method for detecting the terahertz wave T to be detected by using the terahertz wave detection device 10 will be described.

First, as illustrated in FIG. 1, each member is disposed such that the terahertz wave T to be detected is incident on the light incident surface 2a of the QCL element 2. At this time, it is preferable that the polarization surface of the terahertz wave T incident on the light incident surface 2a and the polarization surface of the laser beam L emitted from the light emission surface 2b (surfaces parallel to both the directions D1 and D2) are set to be parallel to each other. For example, the above setting may be performed by disposing the polarizing element 8 between the light source 7 and the QCL element 2, or may be performed by disposing (adjusting the orientation of) the light source 7 or the QCL element 2 without using the polarizing element 8.

In addition, the operation of the QCL element 2 may be controlled such that the first laser beam oscillates and the second laser beam does not oscillate in the first state where the terahertz wave T is not incident on the light incident surface 2a and the second laser beam oscillates in the second state where the terahertz wave T is incident on the light incident surface 2a. The above control (hereinafter, referred to as “first control”.) is performed, for example, by adjusting the drive current I injected from the control unit 11 into the QCL element 2.

In addition, the operation of the QCL element 2 may be controlled such that the difference frequency Δf (=c(λ₁−λ₂)/(λ₁·λ₂)) between the frequency (c/λ₁) of the first laser beam and the frequency (c/λ₂) of the second laser beam substantially coincides with the frequency of the terahertz wave T. The above control (hereinafter, referred to as “second control”.) is performed, for example, by adjusting the drive current I injected from the control unit 11 into the QCL element 2.

Thus, preparation for detecting the terahertz wave T in the optical system 1 is completed. In this state, the signal value indicating the detection result of the photodetector 4 is continuously acquired in a predetermined target period. Here, the “predetermined target period” is a period in which the terahertz wave T to be detected is likely to be generated, and is a period in which the terahertz wave T is desired to be detected in a case where the terahertz wave T is generated (in the present embodiment, in a case where the terahertz wave T is emitted from the light source 7).

Subsequently, the terahertz wave T is detected in accordance with detection of a change (temporal change) in the signal value continuously acquired as described above. In the present embodiment, the second laser beam (laser beam L) is detected by the photodetector 4 only in a case where the terahertz wave T is incident on the light incident surface 2a, and the second laser beam is not detected by the photodetector 4 in other cases. Thus, when the state where the terahertz wave T is not incident on the light incident surface 2a is changed to the state where the terahertz wave T is incident on the light incident surface 2a, the output value (signal value) of the photodetector 4 changes. Accordingly, according to the terahertz wave detection method using the terahertz wave detection device 10, the terahertz wave T can be detected with high sensitivity and at a high speed by detecting the change in the output value (signal value) of the photodetector 4 that occurs in a case where the terahertz wave T is incident on the light incident surface 2a.

In addition, in the terahertz wave detection method, the polarization surface of the terahertz wave T incident on the light incident surface 2a and the polarization surface of the laser beam L are set to be parallel to each other. According to the above configuration, the polarization surface of the terahertz wave T coincides with the polarization surface of the laser beam L (that is, a surface parallel to the direction D1 which is the resonance direction of the QCL element 2 and the direction D2 which is the stacking direction of the active layers 224), and thus, the influence (in the present embodiment, an increase in carriers in the second light emission upper level Lᵤₚ₂) of the terahertz wave T on the active layer 224 can be increased. As a result, changes in the oscillation degrees of the first laser beam and the second laser beam corresponding to the incidence of the terahertz wave T on the light incident surface 2a can be increased, and the terahertz wave T can be detected with higher accuracy.

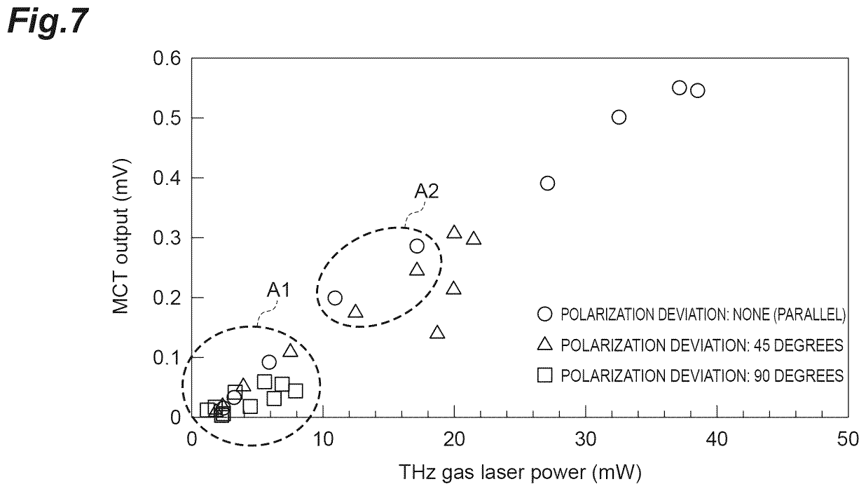

The above effect will be supplemented with reference to FIG. 7. FIG. 7 illustrates a result of measuring an output value (mV) of the photodetector 4 (MCT photodetector) (that is, a signal value corresponding to the intensity of the second laser beam detected by the photodetector 4) while changing output intensity (mW) of the terahertz wave T from the light source 7 for each of a case where the polarization surface of the terahertz wave T and the polarization surface of the laser beam L are parallel to each other (circle), a case where the polarization surfaces are deviated by 45 degrees from each other (triangle), and a case where the polarization surfaces are deviated by 90 degrees from each other (square) by using the optical system 1 by the present inventors. In a region A1 where the output intensity of the terahertz wave T is relatively small, it has been confirmed that a higher output value tends to be obtained by the photodetector 4 in a case where the polarization deviation is small (in the case of the circle or the triangle) than in a case where the polarization deviation is large (in the case of the square). In addition, in a region A2 where the output intensity of the terahertz wave T is medium, it has been confirmed that a higher output value tends to be obtained by the photodetector 4 in a case where there is no polarization deviation (in the case of the circle) than in a case where there is the polarization deviation (in the case of the triangle).

In addition, according to the first control, the second laser beam can be generated only in a case where the terahertz wave T is incident on the light incident surface 2a, and the first laser beam can be reduced by this amount. As a result, a more remarkable difference can be generated between the first state and the second state in the detection amount of the first laser beam or the second laser beam in the photodetector 4 (in the present embodiment, the detection amount of the second laser beam). As a result, the terahertz wave T can be detected with higher accuracy.

In addition, according to the second control, it is possible to suitably increase the changes in the oscillation degrees of the first laser beam and the second laser beam corresponding to the incidence of the terahertz wave T on the light incident surface 2a. In the present embodiment, a large number of carriers are easily supplied to the second light emission upper level Lᵤₚ₂ in accordance with the incidence of the terahertz wave T, and as a result, the second laser beam can be suitably oscillated. As a result, the terahertz wave T can be detected with higher accuracy.

### Modifications

Although the embodiment of the present disclosure has been described above, the present disclosure is not limited to the above embodiment. The material and shape of each configuration are not limited to the above-described material and shape, and various materials and shapes other than the above-described material and shape can be employed. In addition, some configurations included in the above embodiment may be omitted or changed as appropriate.

In the above embodiment, although the optical filter 32 is configured to pass only the second laser beam (λ₂) generated by the terahertz wave T and the photodetector 4 is configured to detect the second laser beam, the optical filter 32 may be configured to pass only the first laser beam (λ₁) oscillating in a steady state where the terahertz wave T is not incident on the QCL element 2, and the photodetector 4 may be configured to detect the first laser beam. As described above, when the terahertz wave T is incident on the light incident surface 2a, it is considered that the oscillation degree of the second laser beam increases while the oscillation degree of the first laser beam decreases. Accordingly, even in a case where the photodetector 4 is configured to detect the first laser beam, a difference in the detection amount of the first laser beam can be detected between the first state and the second state, and the terahertz wave T can be detected based on the difference in the detection amount. That is, in a case where the detection amount of the first laser beam becomes low, it can be determined that the terahertz wave T is incident on the QCL element 2.

In addition, in the terahertz wave detection device 10, when the difference in the detection amount of the first laser beam or the second laser beam occurs between the first state and the second state, the terahertz wave T can be detected by detecting the difference. Accordingly, the QCL element 2 only needs to be configured such that a difference in the detection amount of the first laser beam or the second laser beam occurs at least between the first state and the second state, and may be configured such that both the first laser beam and the second laser beam oscillate in both the first state and the second state.

In addition, in order to detect the terahertz wave to be detected by using the terahertz wave detection device 10, the QCL element 2 may be disposed such that the light incident surface 2a of the QCL element 2 is positioned on the optical path of the terahertz wave, and the present disclosure can be applied to various optical systems other than the optical system 1 of the above embodiment.

In addition, in the above embodiment, although the light incident surface 2a on which the terahertz wave T is incident on the QCL element 2 and the light emission surface 2b from which the mid-infrared light (laser beam L) is emitted are different from each other, the light incident surface and the light emission surface may be the same surface. For example, in the above embodiment, the terahertz wave T may be incident on the light emission surface 2b. In this case, the light emission surface 2b functions as a surface from which the mid-infrared light is emitted and also functions as a light incident surface on which the terahertz wave Tis incident.

What is claimed is:

1. A terahertz wave detection device comprising:
a quantum cascade laser element having a light incident surface on which a terahertz wave to be detected is incident and a light emission surface from which a laser beam different from the terahertz wave is emitted;
an optical component disposed such that the laser beam emitted from the light emission surface passes; and
a photodetector configured to detect the laser beam having passed through the optical component,
wherein the quantum cascade laser element includes:
a substrate; and
a semiconductor layer provided on the substrate, and including an active layer formed with a cascade structure in which a light emitting layer and an injection layer are alternately stacked by stacking unit stacked bodies including the light emitting layer and the injection layer in multiple stages,
in a subband level structure, the unit stacked body has a first light emission upper level, a second light emission upper level that is an energy level higher than the first light emission upper level, and a light emission lower level, and is configured to be able to oscillate a first laser beam that is mid-infrared light having a first wavelength generated by transition from the first light emission upper level to the light emission lower level and a second laser beam that is mid-infrared light having a second wavelength generated by transition from the second light emission upper level to the light emission lower level,
the quantum cascade laser element is configured to change oscillation degrees of the first laser beam and the second laser beam in accordance with the incidence of the terahertz wave on the light incident surface, and
the optical component is configured to cause either one of the first laser beam and the second laser beam to be incident on the photodetector.

2. The terahertz wave detection device according to claim 1, further comprising:
a switch disposed on an upstream side of the light incident surface on an optical path of the terahertz wave and configured to periodically switch between an ON state where the terahertz wave passes and an OFF state where the terahertz wave does not pass; and
a measuring device configured to acquire a first detection signal detected by the photodetector in the ON state and a second detection signal detected by the photodetector in the OFF state based on a signal indicating a repetition frequency of the switch.

3. The terahertz wave detection device according to claim 1, wherein the photodetector is any one of an MCT detector, an InAs detector, an InAsSb detector, and a quantum well infrared detector.

4. The terahertz wave detection device according to claim 1, wherein, in a case where a predetermined drive current corresponding to the terahertz wave is injected, the quantum cascade laser element is configured such that the first laser beam oscillates but the second laser beam does not oscillate in a first state where the terahertz wave is not incident on the light incident surface and the second laser beam oscillates in a second state where the terahertz wave is incident on the light incident surface.

5. The terahertz wave detection device according to claim 1,
wherein the substrate has a first end surface that is an end surface of the substrate on one side in a first direction that is a resonance direction of the quantum cascade laser element and constitutes the light incident surface, and a second end surface that is positioned on a side opposite to the first end surface in the first direction, and
the first end surface is inclined with the first direction to be away from the active layer toward the second end surface side along the first direction.

6. The terahertz wave detection device according to claim 5, wherein an inclination angle of the first end surface with respect to a surface orthogonal to the first direction substantially coincides with a Cherenkov radiation angle corresponding to the active layer.

7. A terahertz wave detection method for detecting a terahertz wave to be detected by using the terahertz wave detection device according to claim 1, the method comprising:
continuously acquiring a signal value indicating a detection result of the photodetector in a predetermined target period; and
detecting the terahertz wave in accordance with detection of a change in the signal value.

8. The terahertz wave detection method according to claim 7, further comprising:
setting a polarization surface of the terahertz wave incident on the light incident surface and a polarization surface of the laser beam emitted from the light emission surface to be parallel to each other.

9. The terahertz wave detection method according to claim 7, further comprising:
controlling an operation of the quantum cascade laser element such that a difference between a frequency of the first laser beam and a frequency of the second laser beam substantially coincides with a frequency of the terahertz wave.

10. The terahertz wave detection method according to claim 7, further comprising:
controlling an operation of the quantum cascade laser element such that the first laser beam oscillates but the second laser beam does not oscillate in a first state where the terahertz wave is not incident on the light incident surface and the second laser beam oscillates in a second state where the terahertz wave is incident on the light incident surface.
